(19) United States
(12) Patent Application Publication
(10) Pub. No.: US 2024/0355821 A1
(43) Pub. Date: Oct. 24, 2024

(54) SEMICONDUCTOR DEVICE AND METHOD FOR FORMING THE SAME

(71) Applicant: TAIWAN SEMICONDUCTOR MANUFACTURING COMPANY LTD., HSINCHU (TW)

(72) Inventors: YUNG-CHIN HOU, TAIPEI (TW); LI-CHUN TIEN, TAINAN CITY (TW); CHIH-LIANG CHEN, HSINCHU CITY (TW); WEI-HUNG WANG, NEW TAIPEI CITY (TW); SHUN LI CHEN, TAINAN CITY (TW); JIANN-TYNG TZENG, HSINCHU (TW)

(21) Appl. No.: 18/303,551

(22) Filed: Apr. 19, 2023

(51) Int. Cl. H01L 27/092; H01L 21/8238

(52) U.S. Cl. CPC H01L 27/0922; H01L 21/82385; H01L 2221/1068

(57) ABSTRACT

A semiconductor device and a method of manufacturing the semiconductor device are provided. The semiconductor device comprises a first electrical conductor, a first additional electrical conductor, a first active region, a second electrical conductor, a second additional electrical conductor, and a second active region. The first electrical conductor has a first width and extends along a first direction. The first additional electrical conductor has a second width and extends along the first direction. The second width is greater than the first width. The first active region extends along a second direction perpendicular to the first direction. The first active region overlaps the first electrical conductor and the first additional electrical conductor from a top view perspective. The second electrical conductor has the first width and extends along the first direction. The second additional electrical conductor has the second width and extends along the first direction.

### BACKGROUND

The present disclosure relates, in general, to semiconductor devices and methods of manufacturing the same. Specifically, the present disclosure relates to semiconductor devices and methods of manufacturing semiconductor products with additional electrical conductors.

Semiconductor devices with cells of different voltages have been widely used for various applications. The electrical conductors coupling to the voltages could be wide to enhance the power efficiency. However, the wide electrical conductors can occupy a large area and reduce area efficiency within limited cell pitch.

### BRIEF DESCRIPTION OF THE DRAWINGS

Aspects of the embodiments of the present disclosure are best understood from the following detailed description when read with the accompanying figures. It should be noted that, in accordance with standard practice in the industry, various structures are not drawn to scale. In fact, the dimensions of the various structures can be arbitrarily increased or reduced for clarity of discussion.

FIG. 1A is a schematic view of a layout of a semiconductor device, in accordance with some embodiments of the present disclosure.

FIG. 1B is a perspective view of a semiconductor device, in accordance with some embodiments of the present disclosure.

FIG. 2A is a schematic view of a layout of a semiconductor device, in accordance with some embodiments of the present disclosure.

FIG. 2B is a perspective view of a semiconductor device, in accordance with some embodiments of the present disclosure.

FIG. 3A is a schematic view of a layout of a semiconductor device, in accordance with some embodiments of the present disclosure.

FIG. 3B is a schematic view of a layout of a semiconductor device, in accordance with some embodiments of the present disclosure.

FIG. 4A is a schematic view of a layout of a semiconductor device, in accordance with some embodiments of the present disclosure.

FIG. 4B is a schematic view of a layout of a semiconductor device, in accordance with some embodiments of the present disclosure.

FIG. 5A is a schematic view of a layout of a semiconductor device, in accordance with some embodiments of the present disclosure.

FIG. 5B is a schematic view of a layout of a semiconductor device, in accordance with some embodiments of the present disclosure.

FIG. 6 is a flowchart showing a method for a semiconductor device, in accordance with some embodiments of the present disclosure.

FIG. 7 is a diagram illustrating an electronic design automation system, in accordance with some embodiments of the present disclosure.

FIG. 8 is a block diagram of an IC layout diagram generation system, in accordance with some embodiments.

FIG. 9 is a block diagram of an IC manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features can be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein may likewise be interpreted accordingly.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially.” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

In some embodiments, cells in a layout diagram (or, alternatively, counterpart cell regions in a corresponding semiconductor device) are isolated from each other by an isolation dummy gate. In some embodiments, an isolation dummy gate which separates first and second portions of an active region within a first cell of a layout diagram (or, alternatively, counterpart first and second cell regions) is referred to as an internal isolation dummy gate whereas each one or more isolation dummy gates which isolate the first cell (alternatively, the counterpart first cell region) from a second cell of the layout diagram (alternatively, a counterpart second cell region in the corresponding semiconductor device) is referred to as an external isolation dummy gate. The isolation dummy gate cuts an active region, causing the aforesaid active region to be discontinuous. The length of an active region affects the mobility of carriers (e.g., hole or electron), resultantly affecting the performance of a semiconductor device. For example, P-type field-effect transistor (FET) tends to have a relatively long active region. Various embodiments of the present disclosure provide layout diagrams (and corresponding semiconductor devices based thereon) that selectively adjust the length of the active regions in either P-type FET and/or N-type FET active regions to improve the performance of the semiconductor device.

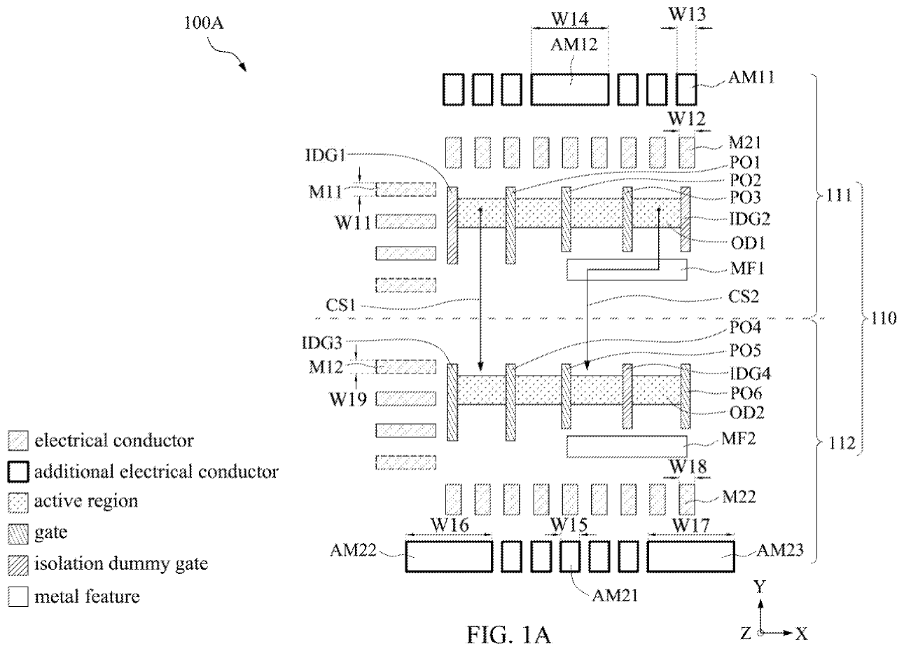

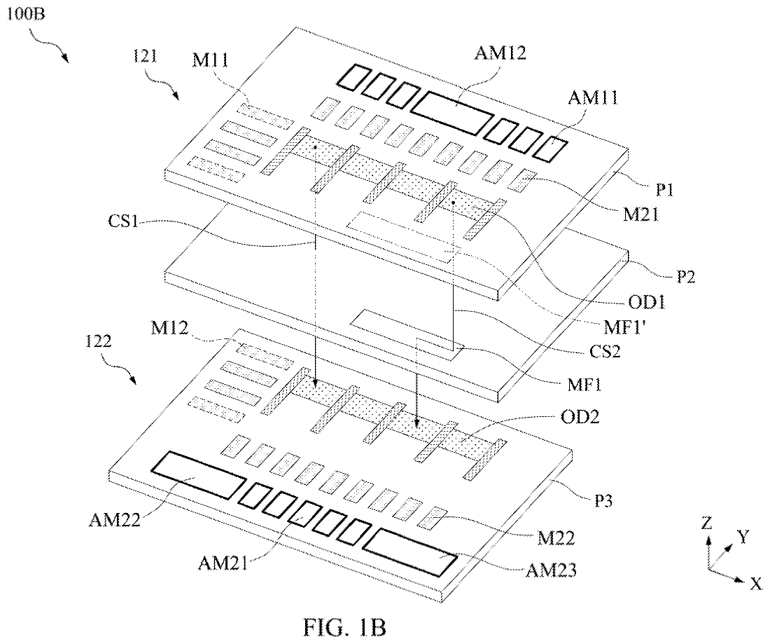

FIG. 1A is a schematic view of a layout of a semiconductor device 100A, in accordance with some embodiments of the present disclosure. In some embodiments, the semiconductor device 100A is applicable to, for example, a planar FET, a Fin Field-Effect Transistor (FinFET), a nanosheet FET, or other suitable FETs.

For simplicity of disclosure, semiconductor device 100A is represented by a layout diagram. The layout diagram of FIG. 1A is representative of semiconductor device 100A; as a practical matter, semiconductor device 100A is fabricated according to the layout diagram of FIG. 1A. In terms of nomenclature, elements in semiconductor device 100A are represented by patterns (also known as shapes) in the layout diagram of FIG. 1A. For simplicity of discussion, most elements in the layout diagram of FIG. 1A (and in other layout diagrams disclosed herein) are referred to as counterpart structures rather than patterns/shapes per se. For example, element PO1 in FIG. 1A is a pattern that represents a gate of a transistor in semiconductor device 100A but is referred to as counterpart gate PO1 rather than as gate pattern PO1. Nevertheless, not all of the elements of semiconductor device 100A are explicitly discussed herein in terms of semiconductor-device-phraseology. For example, a cell region in semiconductor device 100A is referred to as a cell, the abbreviation (cell instead of cell region) reflecting the use of layout-diagram phraseology for an element. Regarding other layout diagrams disclosed herein which are used to represent corresponding semiconductor devices, a nomenclature similar to FIG. 1A is followed.

In some embodiments, the semiconductor device 100A includes active regions OD1 and OD2, gates PO1, PO2, PO3, PO4, PO5, and PO6, electrical conductors M11, M12, M21, and M22, isolation dummy gates IDG1, IDG2, IDG3, and IDG4, metal features MF1 and MF2, and additional electrical conductors AM11, AM12, AM21, AM22, and AM23. It should be noted that the terms “comprise” or “comprising,” “include” or “including,” “have” or “having,” and the like used in this application are to be understood to be open-ended, i.e., to mean: including, but not limited to. Accordingly, various elements and/or structures, which are not shown in FIG. 1A and formed in the semiconductor device 100A, are within the contemplated scope of the present disclosure.

In some embodiments, each of the isolation dummy gates IDG1 to IDG4 is disposed on an edge or a portion of the semiconductor device 100A to electrically isolate the semiconductor device 100A from other semiconductor devices. An isolation dummy gate is a dielectric structure that includes one or more dielectric materials and functions as an electrical isolation structure. Accordingly, an isolation dummy gate is not a structure that is electrically conductive and thus does not function, e.g., as an active gate of a transistor. An isolation dummy gate includes one or more dielectric materials and functions as an electrical isolation structure. In some embodiments, an isolation dummy gate is based on a gate structure as a precursor. In some embodiments, a dummy gate structure includes a gate conductor, a gate-insulator layer, (optionally) one or more spacers, or the like. In some embodiments, an isolation dummy gate is formed by first forming a gate structure, e.g., a dummy gate structure, sacrificing/removing (e.g., etching) the gate conductor of the gate structure to form a trench, (optionally) removing a portion of a substrate that previously had been under the gate conductor to deepen the trench, and then filling the trench with one or more dielectric materials such that the physical dimensions of the resultant electrical isolation structure, i.e., the isolation dummy gate, are similar to the dimensions of the dummy gate conductor which was sacrificed, namely the gate conductor or the combination of the gate conductor and the portion of the substrate. In some embodiments, each of the isolation dummy gates IDG1 to IDG4 is a dielectric feature that includes one or more dielectric materials (e.g., oxide, nitride, oxynitride, or other suitable materials), and functions as an isolation feature. The isolation dummy gates IDG1 to IDG4 extend along a Y direction. In some embodiments, each of the isolation dummy gates IDG1 to IDG4 is a continuous polysilicon on oxide diffusion (OD) edge structure, and is referred to as a CPODE structure.

The gates PO1, PO2, PO3, PO4, PO5, and PO6 extend along the Y direction. The gates PO1 to PO3 are disposed between the isolation dummy gates IDG1 and IDG2. The gates PO4 to PO6 can be staggered or interleaved with the isolation dummy gates IDG3 and IDG4. In some embodiments, each of the gates PO1 to PO3 extends across the active region OD1, and each of the gates PO4 to PO6 extends across the active region OD2.

Each of the gates PO1 to PO6 includes a gate dielectric layer (not shown) and a gate electrode layer (not shown) disposed on the gate dielectric layer. The gate dielectric layer includes silicon oxide (SiOx), silicon nitride (SixNy), silicon oxynitride (SiON), or a combination thereof. The gate dielectric layer includes dielectric material(s), such as high-k dielectric material. The high-k dielectric material has a dielectric constant (k value) greater than 4. The high-k material includes hafnium oxide (HfO2), zirconium oxide (ZrO2), lanthanum oxide (La2O3), yttrium oxide (Y2O3), aluminum oxide (Al2O3), titanium oxide (TiO2) or another applicable material. Other suitable materials are within the contemplated scope of the disclosure.

The gate electrode layer is made of conductive material, such as aluminum (Al), copper (Cu), tungsten (W), titanium (Ti), tantalum (Ta), or other applicable materials. In some embodiments, the gate electrode layer includes a work function layer. The work function layer is made of metal material, and the metal material includes N-work-function metal or P-work-function metal. The N-work-function metal includes tungsten (W), copper (Cu), titanium (Ti), silver (Ag), aluminum (Al), titanium aluminum alloy (TiAl), titanium aluminum nitride (TiAlN), tantalum carbide (TaC), tantalum carbon nitride (TaCN), tantalum silicon nitride (TaSiN), manganese (Mn), zirconium (Zr) or a combination thereof. The P-work-function metal includes titanium nitride (TiN), tungsten nitride (WN), tantalum nitride (TaN), ruthenium (Ru) or a combination thereof. Other suitable materials are within the contemplated scope of the disclosure.

The electrical conductors M11 and M12 extend along the X direction. The electrical conductors M11 and M12 are spaced apart from each other. The electrical conductor M11 could extend across portions of the gates PO1 to PO3 and the isolation dummy gates IDG1 and IDG2 along the X direction, while the electrical conductor M12 could extend across portions of the gates PO4 to PO6 and the isolation dummy gates IDG3 and IDG4 along the X direction. In some embodiments, each of the electrical conductors M11 and M12 is a continuous metal region. The electrical conductor M11 can have a width W11. The electrical conductor M12 can have a width W19. The width W11 can be substantially identical to the width W19.

The electrical conductors M21 and M22 extend along the Y direction. The electrical conductors M21 and M22 are spaced apart from each other. The electrical conductor M21 could extend across portions of the active region OD1 along the Y direction, while the electrical conductor M22 could extend across portions of the active region OD2 along the Y direction. In some embodiments, each of the electrical conductors M21 and M22 is a continuous metal region. The electrical conductor M21 can have a width W12. The electrical conductor M22 can have a width W18. The width W12 can be substantially identical to the width W18.

The additional electrical conductors AM11, AM12. AM21, AM22 and AM23 extend along the Y direction. The additional electrical conductors AM11 to AM23 and the electrical conductors M11 to M22 can be formed at different elevation levels along the Z direction perpendicular to the X direction and Y direction. The additional electrical conductors AM11 to AM23 can be formed above the electrical conductors M11 and M12. The additional electrical conductors AM11 to AM23 can be formed above the electrical conductors M21 and M22. The additional electrical conductors AM11 to AM23 can be formed above the active regions OD1 and OD2. The additional electrical conductors AM11 to AM23 can be formed above the gates PO1 to PO6 and the isolation dummy gates IDG1 to IDG4.

The additional electrical conductors AM11 and AM12 are spaced apart from each other. The additional electrical conductors AM21, AM22 and AM23 are spaced apart from each other. The additional electrical conductors AM11 and AM12 could extend across portions of the active region OD1 along the Y direction, while the additional electrical conductors AM21, AM22 and AM23 could extend across portions of the active region OD2 along the Y direction. In some embodiments, each of the additional electrical conductors AM11 to AM23 is a continuous metal region.

In some embodiments, the width W11 of the electrical conductor M11 can be substantially identical to the width W12 of the electrical conductor M21. The width W13 of the additional electrical conductor AM11 can be substantially identical to the width W12. The width W13 can be different from the width W12. The width W14 of the additional electrical conductor AM12 can be different from the width W13. The width W14 can be greater than the width W13. The width W14 can be more than twice the width W13. The width W14 can be more than three times the width W13.

In some embodiments, the width W18 of the electrical conductor M22 can be substantially identical to the width W19 of the electrical conductor M12. The width W15 of the additional electrical conductor AM21 can be substantially identical to the width W18. The width W15 can be different from the width W18. The width W16 of the additional electrical conductor AM22 can be different from the width W15. The width W16 can be greater than the width W15. The width W16 can be more than twice the width W15. The width W16 can be more than three times the width W15. The width W17 of the additional electrical conductor AM23 can be different from the width W16. The width W17 can be substantially identical to the width W16. The width W17 can be different from the width W15. The width W17 can be greater than the width W15. The width W17 can be more than twice the width W15. The width W17 can be more than three times the width W15.

The active regions OD1 and OD2 extend along the X direction. In some embodiments, each of the active regions OD1 and OD2 is a region with a semiconductor surface wherein various doped features are formed and configured to as one or more devices, such as a diode, a transistor, and/or other suitable active devices. The active regions OD1 and OD2 are spaced apart from each other. In some embodiments, each of the active regions OD1 and OD2 is a continuous active region. In some embodiments, the active region OD1 extends continuously between the isolation dummy gates IDG1 and IDG2 along the X direction. The length of the active region OD1 can be determined or adjusted by the isolation dummy gates IDG1 and IDG2. In some embodiments, the active region OD2 extends continuously between the isolation dummy gate IDG3 and the gate PO6 along the X direction. The length of the active region OD2 can be determined or adjusted by the isolation dummy gate IDG3 and the gate PO6. In some embodiments, the term “active region” discussed in the present disclosure may also be referred to as an oxide dimensioned area. Each of the active regions OD1 and OD2 can be divided into several portions by the gates PO1 to PO6 and the isolation dummy gates IDG1 to IDG4.

The metal features MF1 and MF2 extend along the X direction. Each of the metal features MF1 and MF2 is configured to electrically connect the active region OD1 to the active region OD2. As shown in FIG. 1A, the leftmost portion of the active region OD1 is electrically connected to the leftmost portion of the active region OD2 through the conductive section CS1. The rightmost portion of the active region OD1 is electrically connected to the right-central portion of the active region OD2 through the conductive section CS2, which penetrates and overlaps the metal feature MF1.

The metal features MF1 and MF2 are spaced apart from each other. The metal features MF1 and MF2 are disposed adjacent to the active regions OD1 and OD2, respectively. The metal features MF1 and MF2 can be disposed at different elevation levels. The metal feature MF1 and the active region OD1 can be disposed at different elevation levels. The metal feature MF2 and the active region OD2 can be disposed at different elevation levels. The metal feature MF1 can be provided between the active regions OD1 and OD2 along the Z direction, which is perpendicular to the X direction and the Y direction. The metal feature MF2 can be provided below the active region OD2 along the Z direction.

In some embodiments, the semiconductor device 100A can include a cell 110. The cell 110 can include two cell regions 111 and 112. The cell region 111 includes the active region OD1, the gates PO1 to PO3, the electrical conductors M11 and M21, the isolation dummy gates IDG1 and IDG2, and additional electrical conductors AM11 to AM12. The cell region 112 includes the active region OD2, the gates PO4 to PO6, the electrical conductors M12 and M22, the isolation dummy gates IDG3 and IDG4, and additional electrical conductors AM21 to AM23.

The cell regions 111 and 112 can be formed at different elevation levels. The cell region 111 can be formed above the cell region 112 along the Z direction. Each of the cell regions 111 and 112 can include one or more transistors. The dopant type or conductive type of the transistors in the cell region 111 can be identical to that of the transistors in the cell region 112. The dopant type or conductive type of the transistors in the cell region 111 can be different from that of the transistors in the cell region 112. The cell region 111 can include a PMOS transistor, and the cell region 112 can include an NMOS transistor. The cell 110 as a whole can include a CFET (Complementary FET).

FIG. 1B is a perspective view of a semiconductor device 100B, in accordance with some embodiments of the present disclosure. The semiconductor device 100B can be similar to or correspond to the semiconductor device 100A.

The cell region 121 of the semiconductor device 100B can be similar to or correspond to the cell region 111 of the semiconductor device 100A. The cell region 122 of the semiconductor device 100B can be similar to or correspond to the cell region 112 of the semiconductor device 100A. In some embodiments, the cell region 121, the metal feature MF1, and the cell region 122 are disposed at different elevation levels. The cell region 121 can be formed on a plane P1 extending along the X direction and Y direction. The metal feature MF1 can be formed on a plane P2 extending along the X direction and Y direction. The cell region 122 can be formed on a plane P3 extending along the X direction and Y direction. The planes P1, P2 and P3 can be arranged along the Z direction and parallel with each other.

As shown in FIG. 1B, the projection MF1′ on the plane P1 of the metal feature MF1 on the plane P2 is adjacent to the active region OD1. The projection MF1′ can be parallel with the electrical conductor M11. The projection MF1′ can be perpendicular to the electrical conductor M21 and the additional electrical conductors AM11, AM12. In some embodiments, the leftmost portion of the active region OD1 is electrically connected to the leftmost portion of the active region OD2 through the conductive section CS1. The rightmost portion of the active region OD1 is electrically connected to the right-central portion of the active region OD2 through the conductive section CS2, which penetrates and overlaps the metal feature MF1. The conductive section CS2 can include electrical routing or wiring, which extends along one or a combination of X direction and Y direction.

Although in FIG. 1B, the additional electrical conductors AM11 and AM12 are depicted on the plane P1, it can be conceived that the additional electrical conductors AM11 and AM12 can be located at different elevation levels with the electrical conductors M11 and M21. The additional electrical conductors AM11 and AM12 can be disposed in another plane above the plane P1. Similarly, the additional electrical conductors AM21 to AM23 can be at different elevation levels with the electrical conductors M21 and M22. The additional electrical conductors AM21 to AM23 can be disposed in another plane above the plane P3. The additional electrical conductors AM21 to AM23 can be disposed in another plane below the plane P3. The additional electrical conductors AM21 to AM23 can be disposed in a plane between the planes P2 and P3.

In some embodiments, the additional electrical conductor AM12 can extend along the Y direction and across the active region OD1. The additional electrical conductors AM22 and AM23 can extend along the Y direction and across the active region OD2. The projection on the plane P2 of the additional electrical conductor AM12 can overlap or cover the projection on the plane P2 of the additional electrical conductor AM21. The projection on the plane P2 of the additional electrical conductor AM12 is provided between the projections on the plane P2 of the additional electrical conductors AM22 and AM23. The projection on the plane P2 of the additional electrical conductor AM12 can be spaced apart from the projections on the plane P2 of the additional electrical conductors AM22 and AM23. The projection on the plane P2 of the additional electrical conductor AM12 can overlap a portion of the projections on the plane P2 of the additional electrical conductors AM22 and AM23.

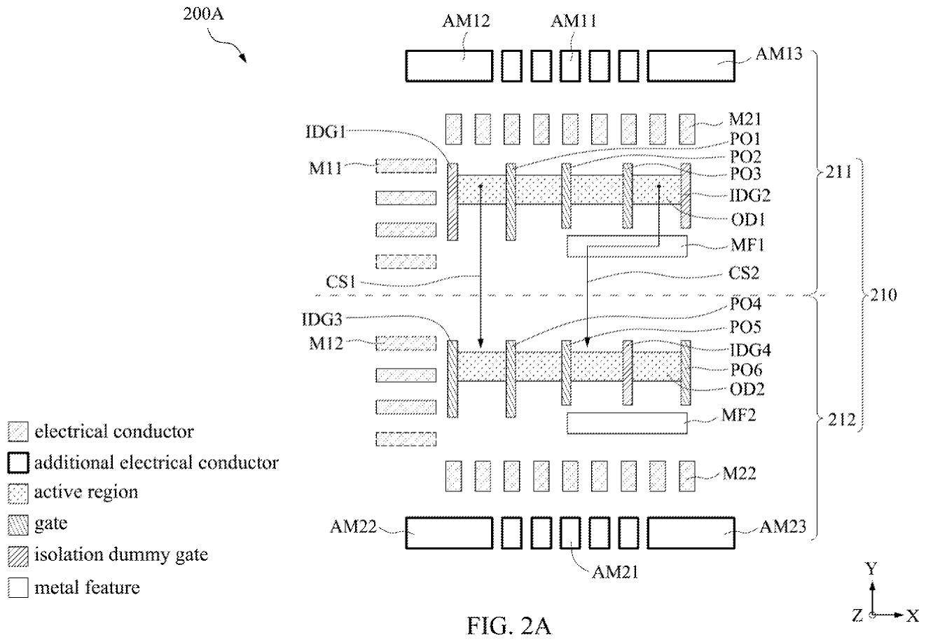

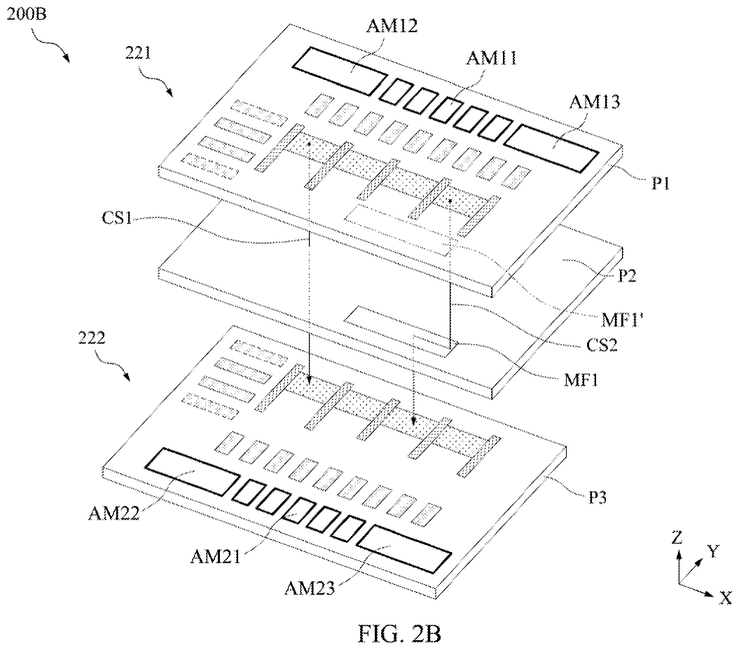

FIG. 2A is a schematic view of a layout of a semiconductor device 200A, in accordance with some embodiments of the present disclosure. The semiconductor device 200A can be similar to the semiconductor device 100A, except for the configuration of the additional electrical conductors AM11 to AM13 and AM21 to AM23 of the semiconductor device 200A.

As shown in FIG. 2A, the cell 210 can include two cell regions 211 and 212. The additional electrical conductors AM11 to AM13 are included in the cell region 211, and the additional electrical conductors AM21 to AM23 are included in the cell region 212. The widths of the additional electrical conductors AM12 and AM13 are greater than the width of the additional electrical conductor AM11. The widths of the additional electrical conductors AM22 and AM23 are greater than the width of the additional electrical conductor AM21.

FIG. 2B is a perspective view of a semiconductor device 200B, in accordance with some embodiments of the present disclosure. The semiconductor device 200B can be similar to or correspond to the semiconductor device 200A.

The cell region 221 of the semiconductor device 200B can be similar to or correspond to the cell region 211 of the semiconductor device 200A. The cell region 222 of the semiconductor device 200B can be similar to or correspond to the cell region 212 of the semiconductor device 200A. In some embodiments, the cell region 221, the metal feature MF1, and the cell region 222 are disposed at different elevation levels. The cell region 221 can be formed on a plane P1 extending along the X direction and Y direction. The metal feature MF1 can be formed on a plane P2 extending along the X direction and Y direction. The cell region 222 can be formed on a plane P3 extending along the X direction and Y direction. The planes P1, P2 and P3 can be arranged along the Z direction and parallel with each other. The projection MF1′ can be parallel with the electrical conductor M11. The leftmost portion of the active region OD1 is electrically connected to the leftmost portion of the active region OD2 through the conductive section CS1. The rightmost portion of the active region OD1 is electrically connected to the right-central portion of the active region OD2 through the conductive section CS2, which penetrates and overlaps the metal feature MF1. The conductive section CS2 can include electrical routing or wiring, which extends along one or a combination of X direction and Y direction.

The additional electrical conductors AM11 to AM13 can extend along the Y direction and across the active region OD1. The additional electrical conductors AM21 to AM23 can extend along the Y direction and across the active region OD2. The projection on the plane P2 of the additional electrical conductor AM12 can overlap or cover the projection on the plane P2 of the additional electrical conductor AM22. The projection on the plane P2 of the additional electrical conductor AM13 can overlap or cover the projection on the plane P2 of the additional electrical conductor AM23. The projection on the plane P2 of the additional electrical conductor AM11 is provided between the projections on the plane P2 of the additional electrical conductors AM22 and AM23. The projection on the plane P2 of the additional electrical conductor AM21 can be spaced apart from the projections on the plane P2 of the additional electrical conductors AM12 and AM13.

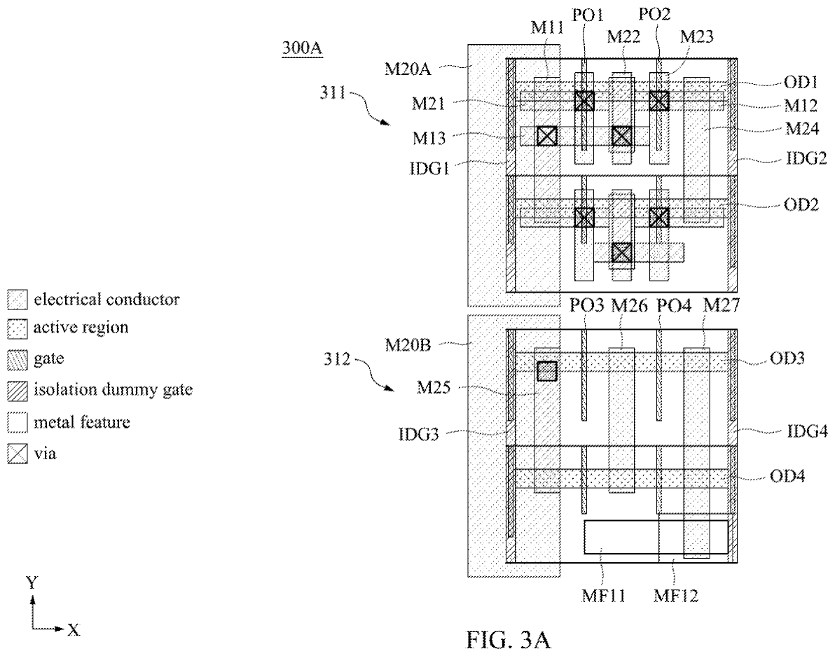

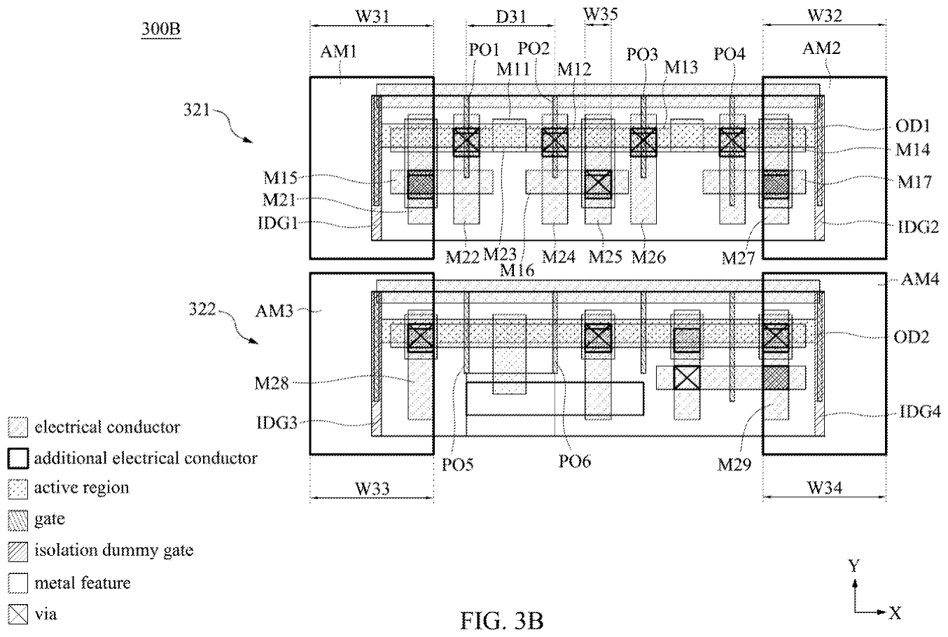

FIG. 3A is a schematic view of a layout of a semiconductor device 300A, in accordance with some embodiments of the present disclosure. The semiconductor device 300A includes two cell regions 311 and 312. The cell region 311 can at least include, for example, active regions OD1 and OD2, gates PO1 and PO2, isolation dummy gates IDG1 and IDG2, electrical conductors M11, M12, M20A, M21, M22, M23 and M24, and several vias. The electrical conductors M11, M22, M23 and M24 extend along the Y direction. The electrical conductors M12 and M21 extend along the X direction. The electrical conductor M11 can be used to electrically connect the active region OD1 and the electrical conductor M13 through a via. The electrical conductor M20A can be electrically coupled to the voltage VSS. The voltage VSS can be received by the source electrode of the semiconductor device 300A.

The cell region 312 can at least include, for example, active regions OD3 and OD4, gates PO3 and PO4, isolation dummy gates IDG3 and IDG4, electrical conductors M20B, M25, M26 and M27, metal features MF11 and MF12, and several vias. The electrical conductors M25, M26 and M27 extend along the Y direction. The electrical conductor M20B can be electrically coupled to the voltage VDD. The voltage VDD can be received by the drain electrode of the semiconductor device 300A.

As illustrated in FIG. 3A, the electrical conductor M20A overlaps or covers the electrical conductor M11 and the isolation dummy gate IDG1. The electrical conductor M20A is wider than other electrical conductors of the cell region 311. The electrical conductor M20A can be at the same elevation level with other electrical conductors of the cell region 311. The electrical conductor M20B overlaps or covers the electrical conductor M25 and the isolation dummy gate IDG3. The electrical conductor M20B can be at the same elevation level with other electrical conductors of the cell region 312. The electrical conductor M20B is wider than other electrical conductors of the cell region 312. Since the electrical conductors M20A and M20B are wide, they can occupy the adjacent trace or routing, and adversely affect the area of the semiconductor device 300A.

FIG. 3B is a schematic view of a layout of a semiconductor device 300B, in accordance with some embodiments of the present disclosure. The semiconductor device 300B can be similar to or correspond to the semiconductor device 300A, except for the additional electrical conductors AM1 to AM4.

The semiconductor device 300B includes two cell regions 321 and 322. The cell region 321 can at least include, for example, the active region OD1, gates PO1 to PO4, isolation dummy gates IDG1 and IDG2, electrical conductors M11 to M27, additional electrical conductors AM1 and AM2, and several vias. The additional electrical conductor AM1 overlaps or covers the isolation dummy gate IDG1 and the electrical conductor M21. The additional electrical conductor AM2 overlaps or covers the isolation dummy gate IDG2 and the electrical conductor M27. The additional electrical conductors AM1 and AM2 can be electrically coupled to the voltage VSS, which can be received by the source electrode of the semiconductor device 300B. The electrical conductors AM1 and AM2 can be at different elevation levels with other electrical conductors of the cell region 321.

The cell region 322 can at least include, for example, the active region OD3, gates PO5 and PO6, isolation dummy gates IDG3 and IDG4, electrical conductors M28 and M29, additional electrical conductors AM3 and AM4, and several vias. The additional electrical conductor AM3 overlaps or covers the isolation dummy gate IDG3 and the electrical conductor M28. The additional electrical conductor AM4 overlaps or covers the isolation dummy gate IDG4 and the electrical conductor M29. The additional electrical conductors AM3 and AM4 can be electrically coupled to the voltage VDD, which can be received by the drain electrode of the semiconductor device 300B. The electrical conductors AM3 and AM4 can be at different elevation levels with other electrical conductors of the cell region 322.

The width W31 of the additional electrical conductor AM1, the width W32 of the additional electrical conductor AM2, the width W33 of the additional electrical conductor AM3 and the width W34 of the additional electrical conductor AM4 are substantially identical to each other. The width W31, the width W32, the width W33 and the width W34 can be different from each other. Each of the widths W31 and W32 can be greater than each of the widths W33 and W34. Each of the widths W31 and W32 can be smaller than each of the widths W33 and W34.

Each of the widths W31 to W34 can be substantially identical to the distance D31 between the gates PO1 and PO2, and the distance D31 can be referred to as the pitch of the semiconductor device 300B. Each of the widths W31 to W34 can be different from the distance D31. Each of the widths W31 to W34 can be in a range of 0.5 times to 1.5 times the distance D31. Each of the widths W31 to W34 can be in a range of 0.2 times to 2 times the distance D31. Each of the widths W31 to W34 can be greater than the width W35 of the electrical conductor M25. The width W35 can be smaller than the distance D31. The width W35 can be substantially identical to the distance D31.

By utilizing the wide additional electrical conductors AM1 to AM4, the power can be enhanced and the resistance drop can be reduced for the semiconductor device 300B to improve the electrical characteristics and reliability. Moreover, the additional electrical conductors AM1 to AM4 are disposed at different elevation levels with other electrical conductors to avoid increasing and sacrificing the area of the semiconductor device 300B. Compared to the semiconductor device 300A in FIG. 3A, the area of the semiconductor device 300B can be reduced from 6 pitches to 5 pitches, and the cell height can be reduced from double-height to single-height. As a result, easier routing can be achieved for smaller cell pitch.

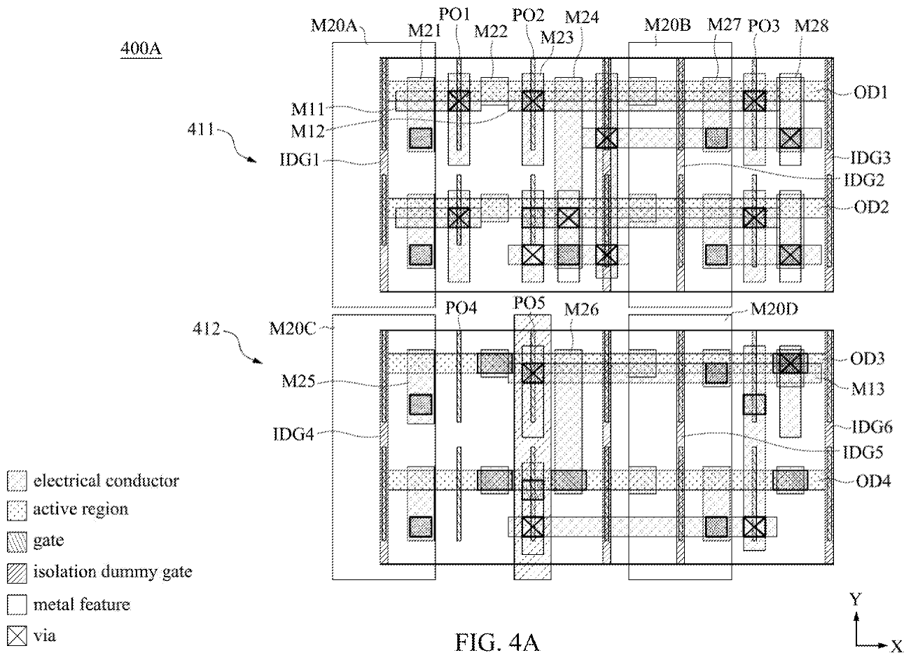

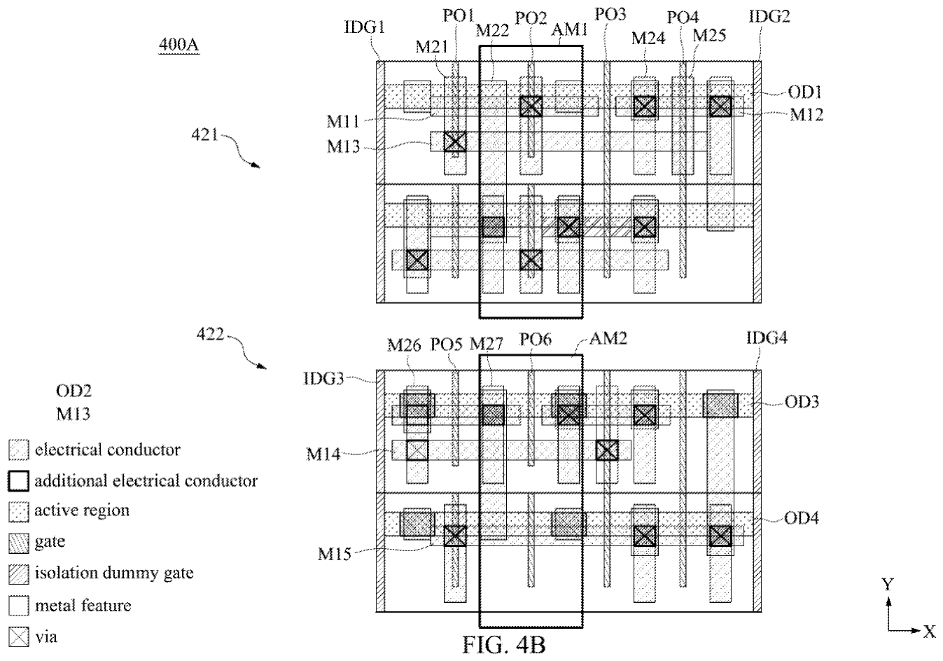

FIG. 4A is a schematic view of a layout of a semiconductor device 400A, in accordance with some embodiments of the present disclosure. The semiconductor device 400A can be similar to or correspond to the semiconductor device 300A, except for the electrical conductors M20A to M20D.

The electrical conductor M20A overlaps or covers the isolation dummy gate IDG1. The electrical conductor M20A and the isolation dummy gate IDG1 can be at the same elevation level. The electrical conductor M20B overlaps or covers the electrical conductor M27 and the isolation dummy gate IDG2. The electrical conductor M20B, the electrical conductor M27 and the isolation dummy gate IDG2 can be at the same elevation level. The electrical conductor M20C overlaps or covers the electrical conductor M25 and the isolation dummy gate IDG3. The electrical conductor M20C, the electrical conductor M25 and the isolation dummy gate IDG3 can be at the same elevation level. The electrical conductor M20D overlaps or covers the isolation dummy gate IDG4 and a portion of the active regions OD3 and OD4. The electrical conductor M20D and the active regions OD3 and OD4 can be at the same elevation level.

FIG. 4B is a schematic view of a layout of a semiconductor device 400B, in accordance with some embodiments of the present disclosure. The semiconductor device 400B can be similar to or correspond to the semiconductor device 400A, except for the additional electrical conductors AM1 and AM2.

The additional electrical conductors AM1 and AM2 can be electrically connected to the same voltage. The additional electrical conductors AM1 and AM2 can be electrically connected to different voltages. For example, the additional electrical conductor AM1 can be electrically connected to the voltage VSS. The additional electrical conductor AM1 can be electrically connected to the voltage VDD.

As shown in FIG. 4B, the additional electrical conductor AM1 can at least overlap the gate PO2, the electrical conductor M22, and a portion of the active regions OD1 and OD2. The additional electrical conductor AM1 can be disposed at a higher elevation level than the gate PO2. The additional electrical conductor AM1 can be disposed at a higher elevation level than the electrical conductor M22. The additional electrical conductor AM1 can be disposed at a higher elevation level than the active regions OD1 and OD2. In some embodiments, the additional electrical conductor AM2 can at least overlap the gate PO6, the electrical conductor M27, and a portion of the active regions OD3 and OD4. The additional electrical conductor AM2 can be disposed at a higher elevation level than the gate PO6. The additional electrical conductor AM2 can be disposed at a higher elevation level than the electrical conductor M27. The additional electrical conductor AM2 can be disposed at a higher elevation level than the active regions OD3 and OD4. In some embodiments, a projection of the additional electrical conductor AM1 on a plane defined by the X direction and Y direction overlaps another projection of the additional electrical conductor AM2 on the plane.

By utilizing the wide additional electrical conductors AM1 and AM2, the power can be enhanced and the resistance drop can be reduced for the semiconductor device 400B to improve the electrical characteristics and reliability. Moreover, the additional electrical conductors AM1 and AM2 are disposed at different elevation levels with other electrical conductors to avoid increasing and sacrificing the area of the semiconductor device 400B. Compared to the semiconductor device 400A in FIG. 4A, the area of the semiconductor device 400B can be reduced from 12 pitches to 10 pitches. As a result, easier routing can be achieved for smaller cell pitch.

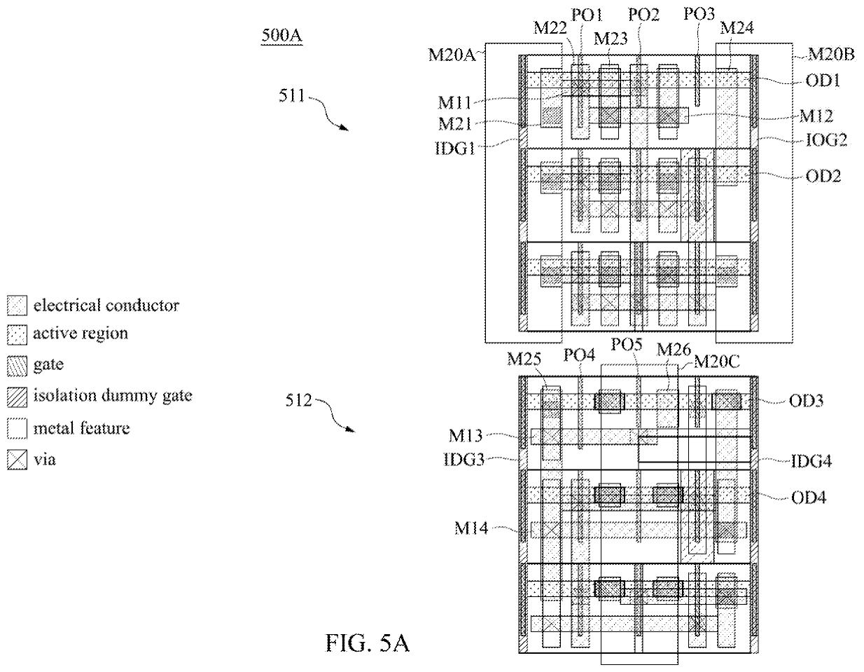

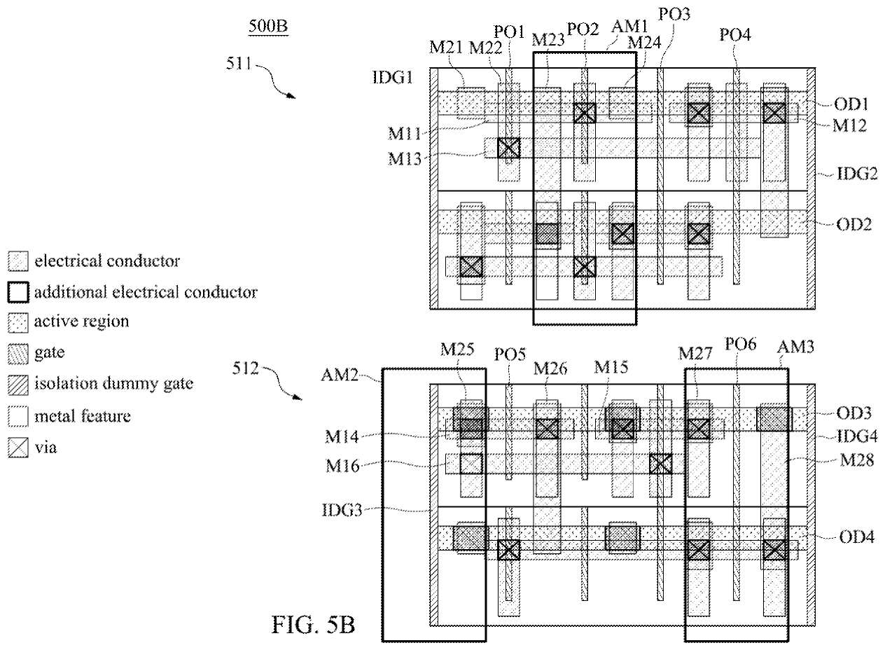

FIG. 5A is a schematic view of a layout of a semiconductor device 500A, in accordance with some embodiments of the present disclosure. The semiconductor device 500A can be similar to or correspond to the semiconductor device 400A, except for the electrical conductors M20A, M20B and M20C.

The electrical conductor M20A overlaps or covers the isolation dummy gate IDG1 and the electrical conductor M21. The electrical conductor M20A, the isolation dummy gate IDG1 and the electrical conductor M21 can be at the same elevation level. The electrical conductor M20B overlaps or covers the isolation dummy gate IDG2 and the electrical conductor M24. The electrical conductor M20B, the isolation dummy gate IDG2 and the electrical conductor M24 can be at the same elevation level. The electrical conductor M20C overlaps or covers the gate PO5 and the electrical conductor M26. The electrical conductor M20C, the gate PO5 and the electrical conductor M26 can be at the same elevation level.

FIG. 5B is a schematic view of a layout of a semiconductor device 500B, in accordance with some embodiments of the present disclosure. The semiconductor device 500B can be similar to or correspond to the semiconductor device 500A, except for the additional electrical conductors AM1 to AM3.

The additional electrical conductors AM1 to AM3 can be electrically connected to the same voltage. The additional electrical conductors AM1 to AM3 can be electrically connected to different voltages. For example, the additional electrical conductor AM1 can be electrically connected to the voltage VSS. The additional electrical conductor AM2 can be electrically connected to the voltage VDD. The additional electrical conductor AM3 can be electrically connected to the voltage VDD.

As shown in FIG. 5B, the additional electrical conductor AM1 can at least overlap the gate PO2, the electrical conductors M23 and M24, and a portion of the active regions OD1 and OD2. The additional electrical conductor AM1 can be disposed above and physically separated from the gate PO2 along the Z direction. The additional electrical conductor AM1 can be disposed above and physically separated from the electrical conductors M23 and M24 along the Z direction. The additional electrical conductor AM1 can be disposed above and physically separated from the active regions OD1 and OD2 along the Z direction.

The additional electrical conductor AM2 can at least overlap the isolation dummy gate IDG3, the electrical conductor M25, and a portion of the active regions OD3 and OD4. The additional electrical conductor AM2 can be disposed above and physically separated from the isolation dummy gate IDG3 along the Z direction. The additional electrical conductor AM2 can be disposed above and physically separated from the electrical conductor M25 along the Z direction. The additional electrical conductor AM2 can be disposed above and physically separated from the active regions OD3 and OD4 along the Z direction.

The additional electrical conductor AM3 can at least overlap the gate PO6, the electrical conductors M27 and M28, and a portion of the active regions OD3 and OD4. The additional electrical conductor AM3 can be disposed above and physically separated from the gate PO6 along the Z direction. The additional electrical conductor AM3 can be disposed above and physically separated from the electrical conductors M27 and M28 along the Z direction. The additional electrical conductor AM3 can be disposed above and physically separated from the active regions OD3 and OD4 along the Z direction.

In some embodiments, a projection of the additional electrical conductor AM1 on a plane defined by the X direction and Y direction can be separated from another projection of the additional electrical conductors AM2 and AM3 on the plane. A projection of the additional electrical conductor AM1 on a plane defined by the X direction and Y direction can be spaced apart from another projection of the additional electrical conductors AM2 and AM3 on the plane.

By utilizing the wide additional electrical conductors AM1 to AM3, the power can be enhanced and the resistance drop can be reduced for the semiconductor device 500B to improve the electrical characteristics and reliability. Moreover, the additional electrical conductors AM1 to AM3 are disposed at different elevation levels with other electrical conductors to avoid increasing and sacrificing the area of the semiconductor device 500B. Compared to the semiconductor device 500A in FIG. 5A, the area of the semiconductor device 300B can be reduced from 12 pitches to 10 pitches. As a result, easier routing can be achieved for smaller cell pitch.

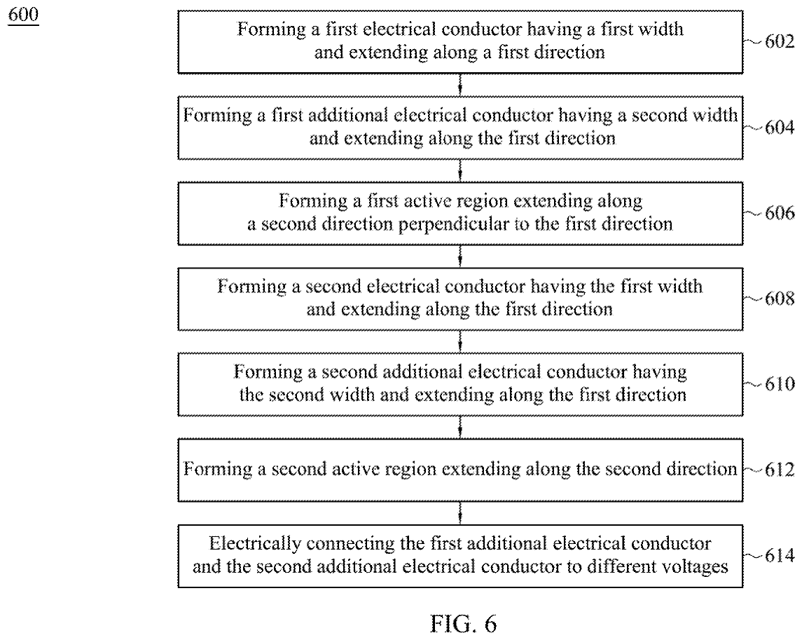

FIG. 6 is a flowchart showing a method 600 for a semiconductor device, in accordance with some embodiments of the present disclosure. In operation 602, a first electrical conductor having a first width and extending along a first direction is formed. In operation 604, a first additional electrical conductor having a second width and extending along the first direction is formed. The second width is greater than the first width. In operation 606, a first active region extending along a second direction perpendicular to the first direction is formed. The first active region overlaps the first electrical conductor and the first additional electrical conductor. In operation 608, a second electrical conductor having the first width and extending along the first direction is formed. In operation 610, a second additional electrical conductor having the second width and extending along the first direction is formed. In operation 612, a second active region extending along the second direction is formed. The second active region overlaps the second electrical conductor and the second additional electrical conductor, and the first transistor is formed above the second transistor along a third direction perpendicular to the first direction and the second direction. In operation 614, the first additional electrical conductor and the second additional electrical conductor are electrically connected to different voltages.

While disclosed methods, such as the method 600, are illustrated and described below as a series of acts or events, it will be appreciated that the illustrated ordering of such acts or events are not to be interpreted in a limiting sense. For example, some operations may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

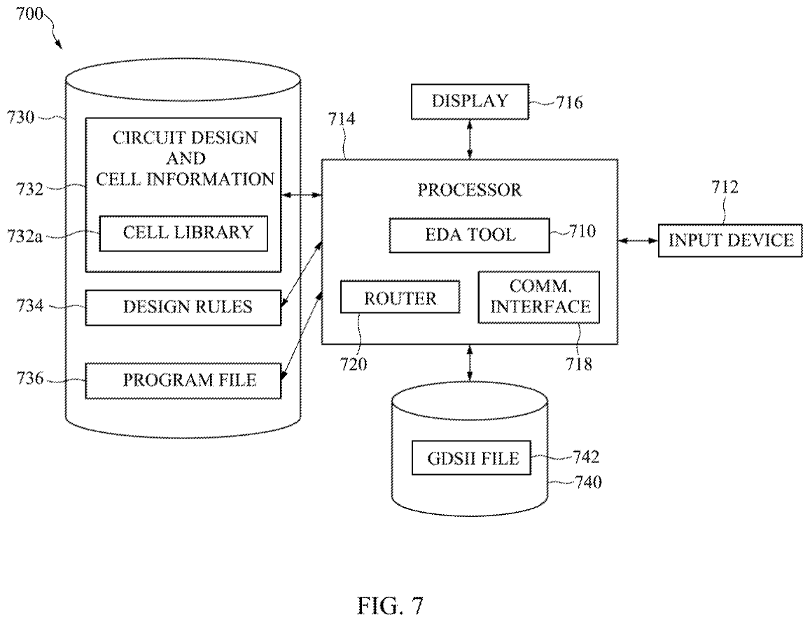

FIG. 7 is a diagram illustrating an electronic design automation system, in accordance with some embodiments of the present disclosure. As shown in FIG. 7, system 700 includes an electronic design automation (“EDA”) tool 710 having a place and route tool including a chip assembly router 720.

The EDA tool 710 is a special purpose computer configured to retrieve stored program instructions 736 from a computer readable storage medium 730 and 740 and execute the instructions on a general purpose processor 714. Processor 714 may be any central processing unit (“CPU”), microprocessor, micro-controller, or computational device or circuit for executing instructions. The non-transitory computer readable storage medium 730 and 740 may be a flash memory, random access memory (“RAM”), read only memory (“ROM”), or other storage medium. Examples of RAMs include, but are not limited to, static RAM (“SRAM”) and dynamic RAM (“DRAM”). ROMs include, but are not limited to, programmable ROM (“PROM”), electrically programmable ROM (“EPROM”), and electrically erasable programmable ROM (“EEPROM”), to name a few possibilities.

System 700 may include a display 716 and a user interface or input device 712 such as, for example, a mouse, a touch screen, a microphone, a trackball, a keyboard, or other device through which a user may input design and layout instructions to system 700. The one or more computer readable storage mediums 730 and 740 may store data input by a user such as a circuit design and cell information 732, which may include a cell library 732a, design rules 734, one or more program files 736, and one or more graphical data system (“GDS”) II files 742.

EDA tool 710 may also include a communication interface 718 allowing software and data to be transferred between EDA tool 710 and external devices. Examples of a communications interface 718 include, but are not limited to, a modem, an Ethernet card, a wireless network card, a Personal Computer Memory Card International Association (“PCMCIA”) slot and card, or the like. Software and data transferred via communications interface 718 may be in the form of signals, which may be electronic, electromagnetic, optical, or the like that are capable of being received by communications interface 718. These signals may be provided to communications interface 718 via a communications path (e.g., a channel), which may be implemented using wire, cable, fiber optics, a telephone line, a cellular link, a radio frequency (“RF”) link and other communication channels. The communications interface 718 may be a wired link and/or a wireless link coupled to a local area network (LAN) or a wide area network (WAN).

Router 720 is capable of receiving an identification of a plurality of cells to be included in a circuit layout, including a list 732 of pairs of cells. The plurality of cells can be connected to each other. In some embodiments, the list 732 can be selected from the cell library 732a. Design rules 734 may be used for a variety of processing technologies. In some embodiments, the design rules 734 configure the router 720 to locate connecting lines and vias on a manufacturing grid. Other embodiments may allow the router to include off-grid connecting lines and/or vias in the layout.

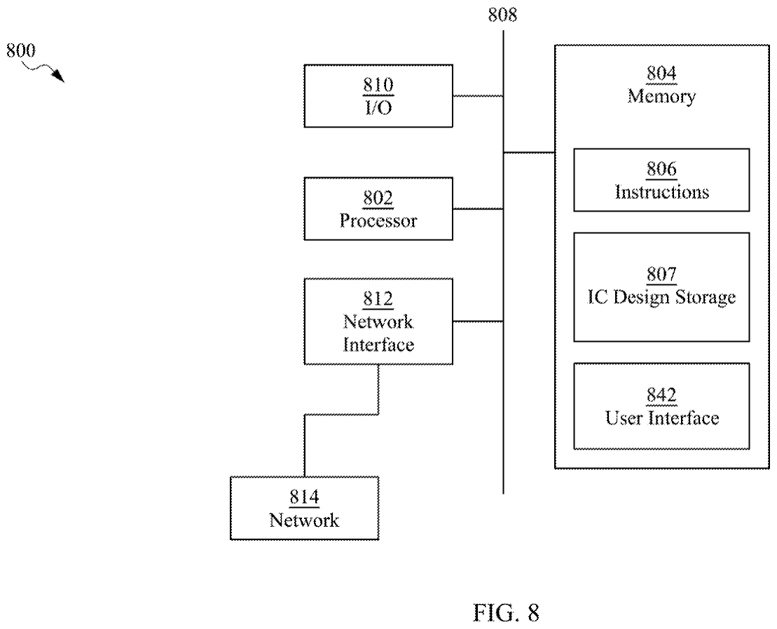

FIG. 8 is a block diagram of IC design system 800, in accordance with some embodiments. Methods described herein of designing IC layout diagrams in accordance with one or more embodiments are implementable, for example, using IC design system 800, in accordance with some embodiments. In some embodiments, IC design system 800 can be an APR system, can include an APR system, or can be a part of an APR system, usable for performing an APR method.

In some embodiments, IC design system 800 includes a processor 802 and non-transitory, computer-readable memory 804. Memory 804, amongst other things, is encoded with, i.e., stores, computer program code, i.e., a set of executable instructions 806. Execution of instructions 806 by the processor 802 represents (at least in part) an EDA tool which implements a portion or all of a method, e.g., a method of generating an IC layout diagram described above (hereinafter, the noted processes and/or methods).

Processor 802 is electrically coupled to computer-readable memory 804 via a bus 808. Processor 802 is also electrically coupled to an I/O interface 810 by bus 808. Network interface 812 is also electrically connected to processor 802 via bus 808. Network interface 812 is connected to a network 814, so that processor 802 and computer-readable memory 804 are capable of connecting to external elements via network 814. Processor 802 is configured to execute instructions 806 encoded in computer-readable memory 804 in order to cause IC design system 800 to be usable for performing a portion or all of the noted processes and/or methods. In one or more embodiments, processor 802 is a central processing unit (CPU), a multi-processor, a distributed processing system, an application specific integrated circuit (ASIC), and/or a suitable processing unit.

In one or more embodiments, memory 804 is an electronic, magnetic, optical, electromagnetic, infrared, and/or a semiconductor system (or apparatus or device). For example, memory 804 includes a semiconductor or solid-state memory, a magnetic tape, a removable computer diskette, a random access memory (RAM), a read-only memory (ROM), a rigid magnetic disk, and/or an optical disk. In one or more embodiments using optical disks, memory 804 includes a compact disk-read only memory (CD-ROM), a compact disk-read/write (CD-R/W), and/or a digital video disc (DVD).

In one or more embodiments, memory 804 stores instructions 806 configured to cause IC design system 800 (where such execution represents (at least in part) the EDA tool) to be usable for performing a portion or all of the noted processes and/or methods. In one or more embodiments, memory 804 also stores information which facilitates performing a portion or all of the noted processes and/or methods. In one or more embodiments, memory 804 includes IC design storage 807 configured to store one or more IC layout diagrams.

IC design system 800 includes I/O interface 810. I/O interface 810 is coupled to external circuitry. In one or more embodiments, I/O interface 810 includes a keyboard, keypad, mouse, trackball, trackpad, touchscreen, and/or cursor direction keys for communicating information and commands to processor 802.

IC design system 800 also includes network interface 812 coupled to processor 802. Network interface 812 allows IC design system 800 to communicate with network 814, to which one or more other computer systems are connected. Network interface 812 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more IC design systems 800.

IC design system 800 is configured to receive information through I/O interface 810. The information received through I/O interface 810 includes one or more of instructions, data, design rules, libraries of standard cells, and/or other parameters for processing by processor 802. The information is transferred to processor 802 via bus 808. IC design system 800 is configured to receive information related to a UI through I/O interface 810. The information is stored in memory 804 as user interface (UI) 842.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by IC design system 800. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

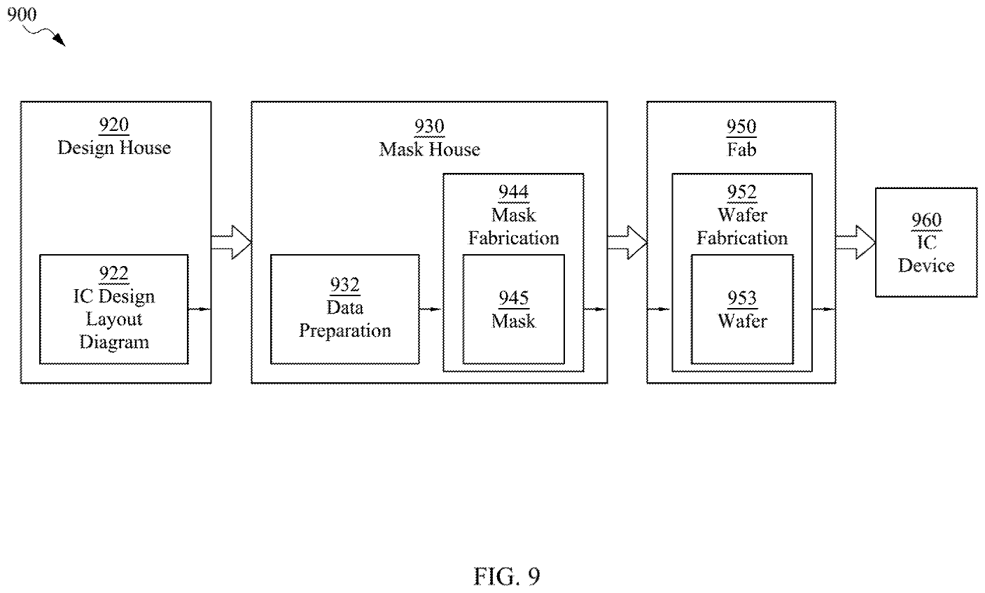

FIG. 9 is a block diagram of IC manufacturing system 900, and an IC manufacturing flow associated therewith, in accordance with some embodiments. In some embodiments, based on an IC layout diagram, at least one of (A) one or more semiconductor masks or (B) at least one component in a layer of a semiconductor integrated circuit is fabricated using manufacturing system 900.

In FIG. 9, IC manufacturing system 900 includes entities, such as a design house 920, a mask house 930, and an IC manufacturer/fabricator (“fab”) 950, that interact with one another in the design, development, and manufacturing cycles and/or services related to manufacturing an IC device 960. The entities in system 900 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 920, mask house 930, and IC fab 950 is owned by a single larger company. In some embodiments, two or more of design house 920, mask house 930, and IC fab 950 coexist in a common facility and use common resources.

Design house (or design team) 920 generates an IC design layout diagram 922. IC design layout diagram 922 includes various geometrical patterns, e.g., an IC layout diagram discussed above. The geometrical patterns correspond to patterns of metal, oxide, or semiconductor layers that make up the various components of IC device 960 to be fabricated. The various layers combine to form various IC features. For example, a portion of IC design layout diagram 922 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 920 implements a proper design procedure to form IC design layout diagram 922. The design procedure includes one or more of logic design, physical design or place and route. IC design layout diagram 922 is presented in one or more data files having information of the geometrical patterns. For example, IC design layout diagram 922 can be expressed in a GDSII file format or DFII file format.

Mask house 930 includes data preparation 932 and mask fabrication 944. Mask house 930 uses IC design layout diagram 922 to manufacture one or more masks 945 to be used for fabricating the various layers of IC device 960 according to IC design layout diagram 922. Mask house 930 performs mask data preparation 932, where IC design layout diagram 922 is translated into a representative data file (RDF). Mask data preparation 932 provides the RDF to mask fabrication 944. Mask fabrication 944 includes a mask writer. A mask writer converts the RDF to an image on a substrate, such as mask (reticle) 945 or a semiconductor wafer 953. The design layout diagram 922 is manipulated by mask data preparation 932 to comply with particular characteristics of the mask writer and/or requirements of IC fab 950. In FIG. 9, mask data preparation 932 and mask fabrication 944 are illustrated as separate elements. In some embodiments, mask data preparation 932 and mask fabrication 944 can be collectively referred to as mask data preparation.

In some embodiments, mask data preparation 932 includes optical proximity correction (OPC) which uses lithography enhancement techniques to compensate for image errors, such as those that can arise from diffraction, interference, other process effects and the like. OPC adjusts IC design layout diagram 922. In some embodiments, mask data preparation 932 includes further resolution enhancement techniques (RET), such as off direction illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 932 includes a mask rule checker (MRC) that checks the IC design layout diagram 922 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 922 to compensate for limitations during mask fabrication 944, which may undo part of the modifications performed by OPC in order to meet mask creation rules.

In some embodiments, mask data preparation 932 includes lithography process checking (LPC) that simulates processing that will be implemented by IC fab 950 to fabricate IC device 960. LPC simulates this processing based on IC design layout diagram 922 to create a simulated manufactured device, such as IC device 960. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 922.

It should be understood that the description of mask data preparation 932 has been simplified for the purposes of clarity. In some embodiments, data preparation 932 includes additional features such as a logic operation (LOP) to modify the IC design layout diagram 922 according to manufacturing rules. Additionally, the processes applied to IC design layout diagram 922 during data preparation 932 may be executed in a variety of different orders.

After mask data preparation 932 and during mask fabrication 944, a mask 945 or a group of masks 945 are fabricated based on the modified IC design layout diagram 922. In some embodiments, mask fabrication 944 includes performing one or more lithographic exposures based on IC design layout diagram 922. In some embodiments, an electron-beam (e-beam) or a mechanism of multiple e-beams is used to form a pattern on a mask (photomask or reticle) 945 based on the modified IC design layout diagram 922. Mask 945 can be formed in various technologies. In some embodiments, mask 945 is formed using binary technology. In some embodiments, a mask pattern includes opaque regions and transparent regions. A radiation beam, such as an ultraviolet (UV) or EUV beam, used to expose the image sensitive material layer (e.g., photoresist) which has been coated on a wafer, is blocked by the opaque region and transmits through the transparent regions. In one example, a binary mask version of mask 945 includes a transparent substrate (e.g., fused quartz) and an opaque material (e.g., chromium) coated in the opaque regions of the binary mask. In another example, mask 945 is formed using a phase shift technology. In a phase shift mask (PSM) version of mask 945, various features in the pattern formed on the phase shift mask are configured to have proper phase difference to enhance the resolution and imaging quality. In various examples, the phase shift mask can be attenuated PSM or alternating PSM. The mask(s) generated by mask fabrication 944 is used in a variety of processes. For example, such a mask(s) is used in an ion implantation process to form various doped regions in semiconductor wafer 953, in an etching process to form various etching regions in semiconductor wafer 953, and/or in other suitable processes.

IC fab 950 is an IC fabrication business that includes one or more manufacturing facilities for the fabrication of a variety of different IC products. In some embodiments, IC Fab 950 is a semiconductor foundry. For example, there may be a manufacturing facility for the front-end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 950 includes wafer fabrication tools 952 configured to execute various manufacturing operations on semiconductor wafer 953 such that IC device 960 is fabricated in accordance with the mask(s), e.g., mask 945. In various embodiments, fabrication tools 952 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 950 uses mask(s) 945 fabricated by mask house 930 to fabricate IC device 960. Thus, IC fab 950 at least indirectly uses IC design layout diagram 922 to fabricate IC device 960. In some embodiments, semiconductor wafer 953 is fabricated by IC fab 950 using mask(s) 945 to form IC device 960. In some embodiments, the IC fabrication includes performing one or more lithographic exposures based at least indirectly on IC design layout diagram 922. Semiconductor wafer 953 includes a silicon substrate or other proper substrate having material layers formed thereon. Semiconductor wafer 953 further includes one or more of various doped regions, dielectric features, multilevel interconnects, and the like (formed at subsequent manufacturing steps).

Some embodiments of the present disclosure provide a semiconductor device. The semiconductor device includes a first transistor and a second transistor. The first transistor includes a first electrical conductor, a first additional electrical conductor, and a first active region. The first transistor includes a second electrical conductor, a second additional electrical conductor, and a second active region. The first electrical conductor has a first width and extends along a first direction. The first additional electrical conductor has a second width and extends along the first direction. The second width is greater than the first width. The first active region extends along a second direction perpendicular to the first direction. The first active region overlaps the first electrical conductor and the first additional electrical conductor from a top view perspective. The second electrical conductor has the first width and extends along the first direction. The second additional electrical conductor has the second width and extends along the first direction. The second active region extends along the second direction. The second active region overlaps the second electrical conductor and the second additional electrical conductor from the top view perspective. The first transistor and the second transistor are disposed at different elevation levels.

Some embodiments of the present disclosure provide a semiconductor device. The semiconductor device includes a first electrical conductor, a plurality of first gates, a first additional electrical conductor and a first active region. The first electrical conductor has a first width and extends along a first direction. The first gates extend along the first direction. Any two adjacent ones of the first gates are spaced apart by a first distance. The first additional electrical conductor has a second width and extends along the first direction. The first additional electrical conductor overlaps the first electrical conductor or one of the first gates from a top view perspective. The first active region extends along a second direction perpendicular to the first direction. The first active region overlaps the first electrical conductor from the top view perspective, the first gates and the first additional electrical conductor. The second width is greater than the first width.

Some embodiments of the present disclosure provide a method for manufacturing a semiconductor device. The method includes forming a first electrical conductor having a first width and extending along a first direction; forming a first additional electrical conductor having a second width and extending along the first direction, wherein the second width is greater than the first width; forming a first active region extending along a second direction perpendicular to the first direction, wherein the first active region overlaps the first electrical conductor and the first additional electrical conductor; forming a second electrical conductor having the first width and extending along the first direction; forming a second additional electrical conductor having the second width and extending along the first direction; and forming a second active region extending along the second direction, wherein the second active region overlaps the second electrical conductor and the second additional electrical conductor, and the first transistor is formed above the second transistor along a third direction perpendicular to the first direction and the second direction.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first transistor, comprising:
a first electrical conductor having a first width and extending along a first direction;
a first additional electrical conductor having a second width and extending along the first direction, wherein the second width is greater than the first width;
a first active region extending along a second direction perpendicular to the first direction, wherein the first active region overlaps the first electrical conductor and the first additional electrical conductor from a top view perspective;
a second transistor, comprising:
a second electrical conductor having the first width and extending along the first direction;
a second additional electrical conductor having the second width and extending along the first direction;
a second active region extending along the second direction, wherein the second active region overlaps the second electrical conductor and the second additional electrical conductor from the top view perspective, and the first transistor and the second transistor are disposed at different elevation levels.

2. The semiconductor device of claim 1, wherein the first transistor comprises a PMOS transistor, and the second transistor comprises a NMOS transistor.

3. The semiconductor device of claim 1, wherein the first electrical conductor and the second electrical conductor are electrically connected to a first voltage or a second voltage, the first additional electrical conductor is electrically connected to one of the first voltage and the second voltage, and the second additional electrical conductor is electrically connected to another one of the first voltage and the second voltage.

4. The semiconductor device of claim 3, wherein the first additional electrical conductor is electrically connected to the second voltage, and the second additional electrical conductor is electrically connected to the first voltage.

5. The semiconductor device of claim 1, wherein a first projection of the first additional electrical conductor on a plane defined by the first direction and the second direction overlaps a second projection of the second additional electrical conductor on the plane.

6. The semiconductor device of claim 1, wherein a first projection of the first additional electrical conductor on a plane defined by the first direction and the second direction is separated from a second projection of the second additional electrical conductor on the plane.

7. The semiconductor device of claim 1, further comprising:
a plurality of first gates extending along the first direction and overlapping the first active region from the top view perspective; and
a plurality of second gates extending along the first direction and overlapping the second active region from the top view perspective.

8. The semiconductor device of claim 7, wherein any two adjacent ones of the first gates are spaced apart by a first distance, any two adjacent ones of the second gates are spaced apart by the first distance, and the second width is substantially identical to the first distance.

9. The semiconductor device of claim 8, wherein the second width is in a range of 0.5 times the first distance to 1.5 times the first distance.

10. A semiconductor device, comprising:
a first electrical conductor having a first width and extending along a first direction;
a plurality of first gates extending along the first direction, wherein any two adjacent ones of the first gates are spaced apart by a first distance;
a first additional electrical conductor having a second width and extending along the first direction, wherein the first additional electrical conductor overlaps the first electrical conductor or one of the first gates from a top view perspective; and
a first active region extending along a second direction perpendicular to the first direction, wherein the first active region overlaps the first electrical conductor from the top view perspective, the first gates and the first additional electrical conductor, wherein the second width is greater than the first width.

11. The semiconductor device of claim 10, wherein the second width is different from the first distance.

12. The semiconductor device of claim 10, wherein the second width is in a range of 0.5 times the first distance to 1.5 times the first distance.

13. The semiconductor device of claim 10, further comprising:
a second electrical conductor having a first width and extending along the first direction;
a plurality of second gates extending along the first direction, wherein any two adjacent ones of the second gates are spaced apart by the first distance;
a second additional electrical conductor having the second width and extending along the first direction, wherein the first additional electrical conductor overlaps the second electrical conductor or one of the second gates from the top view perspective; and
a second active region extending along the second direction, wherein the third active region overlaps the second electrical conductor, the second gates and the second additional electrical conductor from the top view perspective,
wherein the second width is greater than the first width, and the second width is substantially identical to the first distance.

14. The semiconductor device of claim 13, further comprising:
a first transistor, comprising the first electrical conductor, the first gates, the first additional electrical conductor and the first active region; and
a second transistor, comprising the second electrical conductor, the second gates, the second additional electrical conductor and the second active region,
wherein a conductive type of the first transistor is different from that of the second transistor.

15. The semiconductor device of claim 14, wherein the first transistor is formed above the second transistor along a third direction perpendicular to the first direction and the second direction.

16. The semiconductor device of claim 13, wherein the first additional electrical conductor and the second additional electrical conductor are electrically connected to different voltages.

17. The semiconductor device of claim 13, wherein a first projection of the first additional electrical conductor on a plane defined by the first direction and the second direction overlaps a second projection of the second additional electrical conductor on the plane.

18. The semiconductor device of claim 13, wherein a first projection of the first additional electrical conductor on a plane defined by the first direction and the second direction is spaced apart from a second projection of the second additional electrical conductor on the plane.

19. A method for manufacturing a semiconductor device, comprising:
forming a first electrical conductor having a first width and extending along a first direction;
forming a first additional electrical conductor having a second width and extending along the first direction, wherein the second width is greater than the first width;
forming a first active region extending along a second direction perpendicular to the first direction, wherein the first active region overlaps the first electrical conductor and the first additional electrical conductor;
forming a second electrical conductor having the first width and extending along the first direction;
forming a second additional electrical conductor having the second width and extending along the first direction; and
forming a second active region extending along the second direction, wherein the second active region overlaps the second electrical conductor and the second additional electrical conductor, and the first transistor is formed above the second transistor along a third direction perpendicular to the first direction and the second direction.

20. The method of claim 19, further comprising:
electrically connecting the first additional electrical conductor and the second additional electrical conductor to different voltages.
